(19) United States
(12) Patent Application Publication
(10) Pub. No.: US 2025/0005223 A1
(43) Pub. Date: Jan. 2, 2025

(54) IDENTIFICATION OF PATTERNS FOR FINITE STATE MACHINE MODELED SYSTEMS

(71) Applicant: GM GLOBAL TECHNOLOGY OPERATIONS LLC, Detroit, MI (US)

(72) Inventors: Zahy Bnaya, Petach Tikva (IL); Daniel Y. Rubin, Holon (IL); Asaf Degani, Tel Aviv (IL); Yael Shmueli Friedland, Tel Aviv (IL); Shani Avnet, Tel Aviv (IL)

(73) Assignee: GM GLOBAL TECHNOLOGY OPERATIONS LLC, Detroit, MI (US)

(21) Appl. No.: 18/343,243

(22) Filed: Jun. 28, 2023

(51) Int. Cl. G06F 30/20; G06F 9/448

(52) U.S. Cl. CPC G06F 30/20; G06F 9/4498

(57) ABSTRACT

A supportive software-based “toolbox” for recognizing patterns in finite state machine (FSM)-modeled systems. The pattern recognition may include identifying data associated with a design of a finite state machine (FSM)-modeled system from a user device, determining a design analysis model from one more annotated or existing designs, and identifying one or more system patterns within the FSM-modeled system based on searching the FSM-modeled system according to the design analysis model.

### INTRODUCTION

The present disclosure relates to a supportive software-based “toolbox” for aiding in the design and implementation of a finite state machine (FSM)-modeled systems having multiple states, state transitions/mode changes, and other potentially complex behavior. The present approach is intended to aid system designers, programmers, and other users during the system design process by identifying patterns.

Finite state machines are mathematical abstractions frequently used to design and validate the behavior of a myriad of different software programs and physical systems. A finite state machine may be graphically represented as a stateflow diagram, state transition table, or hierarchical state machine/diagram, e.g., a Statechart. FSM-modeled systems begin from an initial state. Based on the present state of the designed system and a given single event or combination of events (“super events”), a finite state machine is able to transition between various additional states in response to system inputs or triggering events. Although the state transition table or stateflow diagram is instrumental to the overall system design process, the design of the FSM-modeled system may benefit from identifying patterns therein, such as to identify patterns of best practices, problematic patterns, etc.

### SUMMARY

Disclosed herein are automated systems and associated methods for aiding a user, e.g., a software programmer, designer, or system developer, in the identification of patterns, such as but not necessarily limited to identifying best practices, faults, and other patterns that may be found in a finite state machine (FSM)-modeled system. The automated methodology contemplated herein is particularly well suited for designing systems having relatively complex and/or highly interactive behavioral traits, e.g., across a wide range of possible states, state transitions, state or mode-triggering events, and outputs. For instance, motor vehicles having automation control capabilities have relatively complex operating modes and state transition rules. Some of these modes are executed automatically or in response to driver inputs, while other modes may be based on timers, hidden logic, or other automatically occurring activation criteria. Other complex systems such as avionics, medical devices, and associated control logic for a wide range of mobile or stationary systems are designed using finite state machine techniques, and would likewise benefit from the automated verification method as described in detail below.

One non-limiting aspect of the present disclosure relates to a pattern recognition platform. The pattern recognition platform may include a system design module configured for receiving data associated with a design of a finite state machine (FSM)-modeled system from a user device. The data may describe static properties, dynamic properties, structural properties, states, state transitions, events, and outputs of the FSM-modeled system. The pattern recognition platform may further include a hypothesis generation module configured for determining a design analysis model from one or more existing designs. The design analysis model may be operable for training pattern searching of the FSM-modeled system according to the static properties, dynamic properties, structural properties, states, state transitions, events, and outputs. The pattern recognition platform may further include a design scanner module configured for identifying one or more system patterns within the FSM-modeled system based on searching the FSM-modeled system according to the design analysis model.

The pattern recognition platform may further include a likelihood estimation module configured for generating a pattern score for each of the system patterns.

The pattern recognition platform may further include a threshold module configured for providing one or more threshold scores for comparison with one or more of the pattern scores.

The pattern recognition platform may further include a notifications module configured for generating a notification to indicate one or more actions for the FSM-modeled system based on comparing the pattern scores to threshold scores.

The notification may be operable for identifying one or more of the system patterns as at least one of good, bad, and of interest to a design team.

The notification may include an identification and location within the FSM-modeled system for one or more of the system patterns.

The static properties may include attributes and behaviors for one or more of the states.

The structural properties may include one or more graph patterns for a subset of one or more of the states and the state transitions.

The dynamic properties may include one more equations or mathematical representation for a subset of one more of the states and the state transitions.

The hypothesis generation module may be configured for determining the design analysis model using at least one of a machine learning algorithm and a neural network.

The hypothesis generation module may be configured for determining the design analysis model using one or more annotated or existing designs.

The annotated or existing designs may include information associated with determining the identification and the location of the one or more system patterns within the FSM-modeled system.

One or more of the pattern scores may be determined using at least one of a weighted average or a sigmoid function.

One or more of the threshold scores may be predetermined from the user device or calculated with the user device.

One non-limiting aspect of the present disclosure relates to a method for pattern recognition. The method may include receiving data associated with a design of a finite state machine (FSM)-modeled system from a user device, determining a design analysis model from one or more annotated or existing designs, and identifying one or more system patterns within the FSM-modeled system based on searching the FSM-modeled system according to the design analysis model.

The method may further include training pattern searching of the FSM-modeled system according to static properties, dynamic properties, structural properties, states, state transitions, events, and outputs identified for the FSM-modeled system.

The method may further include generating a pattern score for each of the system patterns, providing one or more threshold scores for comparison with one or more of the pattern scores, and generating a notification to indicate one or more actions for the FSM-modeled system based on comparing the pattern scores to the threshold scores.

The method may further include identifying one or more of the system patterns as at least one of good, bad, and of interest to a design team.

One non-limiting aspect of the present disclosure relates to a pattern recognition platform. The pattern recognition platform may include a system design module configured for receiving data associated with a design of a finite state machine (FSM)-modeled system, a hypothesis generation module configured for determining a design analysis model from one or more existing designs, a design scanner module configured for identifying one or more system patterns within the FSM-modeled system based on searching the FSM-modeled system according to the design analysis model, a likelihood estimation module configured for generating a pattern score for each of the system patterns, a threshold module configured for providing one or more threshold scores for comparison with one or more of the pattern scores, and a notifications module configured for generating a notification to indicate one or more actions for the FSM-modeled system based on comparing the pattern scores to the threshold scores.

The pattern recognition platform may further include the notifications module configured for identifying one or more of the system patterns as at least one of good, bad, and of interest to a design team.

The above features and advantages, and other features and attendant advantages of this disclosure, will be readily apparent from the following detailed description of illustrative examples and modes for carrying out the present disclosure when taken in connection with the accompanying drawings and the appended claims. Moreover, this disclosure expressly includes combinations and sub-combinations of the elements and features presented above and below.

### BRIEF DESCRIPTION OF THE DRAWINGS

The accompanying drawings, which are incorporated into and constitute a part of this specification, illustrate implementations of the disclosure and together with the description, serve to explain the principles of the disclosure. The appended drawings are not necessarily to scale, and may present a somewhat simplified representation of various preferred features of the present disclosure as disclosed herein, including, for example, specific dimensions, orientations, locations, and shapes. Details associated with such features will be determined in part by the particular intended application and use environment.

FIG. 1 illustrates an automated system for use in designing and implementing a system using finite state machine (FSM)-based design techniques, with the automated system being configured to recognize and address patterns within the designed system in accordance with the disclosure.

FIG. 1A illustrates an exemplary embodiment of distributed processing nodes for use in implementing portions of the automated system shown in FIG. 1.

FIG. 2 illustrates a pattern recognition method in accordance with the disclosure.

FIG. 3 is a flow diagram of a method for recognizing patterns in accordance with an embodiment of the disclosure.

### DETAILED DESCRIPTION

The present disclosure may be embodied in many different forms. Representative examples of the disclosure are shown in the drawings and described herein in detail as non-limiting examples of the disclosed principles. To that end, elements and limitations described in the Abstract, Introduction, Summary, and Detailed Description sections, but not explicitly set forth in the claims, should not be incorporated into the claims, singly or collectively, by implication, inference, or otherwise.

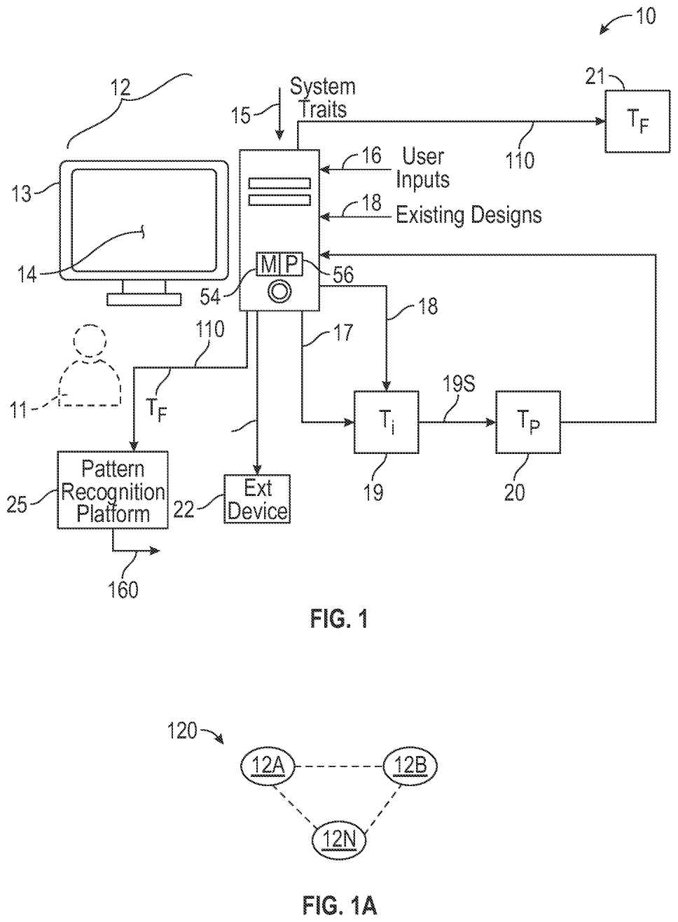

Referring to the drawings, wherein like reference numbers refer to like features throughout the several views, FIG. 1 depicts an automated system 10 configured to recognize patterns within a finite state machine (FSM)-modeled system. Due to the criticality of achieving as close to a perfect understanding and implementation of a designed system as is possible in the design process, and to develop systems that are free of incorrect structures that can lead to design errors and incorrect user interaction, it is useful to verify that the designed system and associated human-machine interfaces will behave in a logical manner and also that their behavior is such that is expected by a user 11, e.g., a designer or programmer, as opposed to a driver, pilot, or other end user of a physical embodiment of the modeled system. An ability to recognize patterns in the FSM-modeled system, or what may be generically referred to herein as system patterns, may be supportive in providing a software-based “toolbox” for aiding a design team.

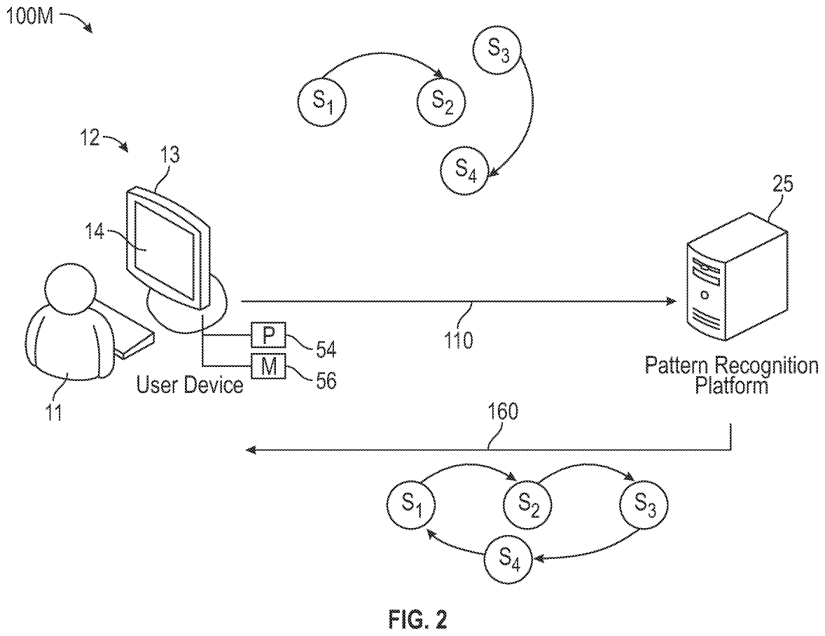

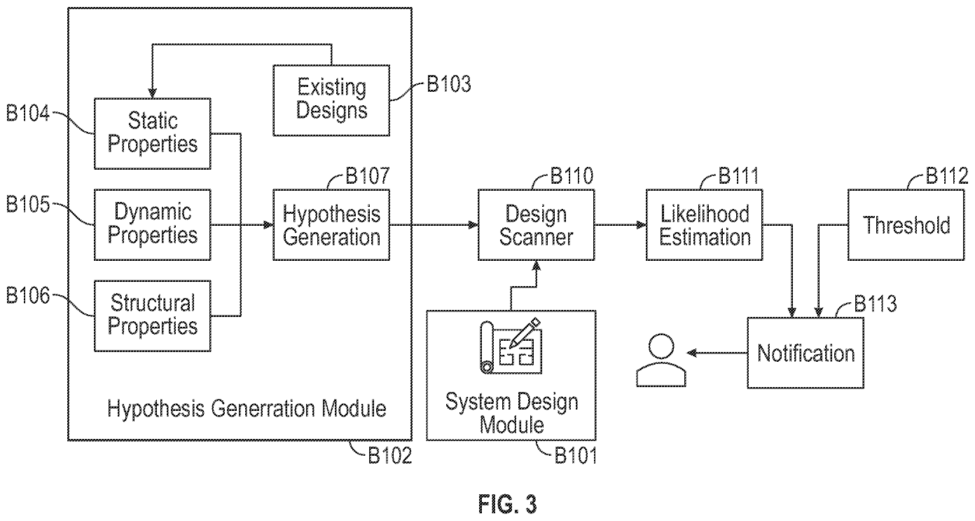

To that end, the present solutions make it possible for the user 11 to identify and catalog system patterns within the FSM-modeled system. Additionally, the present approach supports a structured hierarchical design of the modeled system as set forth herein. As described in detail below with reference to FIGS. 2 and 3, the automated system 10 as contemplated herein has a goal to generalize a given set of annotated/marked locations of system patterns in existing system and use this generalization to identify locations for similar or related patterns in the FSM-modeled.

The automated system 10 illustrated in FIG. 1 may include a user device 12, e.g., a laptop computer, tablet computer, desktop computer, mobile application (“app”), or another application-suitable host machine configured for assisting the user 11 in the design of potentially complex hardware and/or software-based system, or another application-suitable host machine configured for assisting the user 11 in the design of potentially complex hardware and/or software-based system. Although the user device 12 is depicted in FIG. 1 as a single computer device for illustrative simplicity, those skilled in the art will appreciate that the user device 12 could be implemented as a distributed user device 120 having multiple processing nodes, e.g., 12A, 12B, . . . , 12N, as depicted schematically in FIG. 1A. Such processing nodes may be in communication with one another over suitable wired, wireless, and/or cloud-based networked connections. Underlying systems benefitting from the automated system 10 to design human-machine interfaces (“HMIs”) or other devices aboard a motor vehicle or an aircraft, watercraft, rail vehicle, or another dynamic system, or to model performance of a medical device, powerplant, or another static system.

The automated system 10 illustrated in FIG. 1 may also include one or more peripheral devices 13, including a display screen 14 operable as an output device for the user device 12. The user 11 may interact with the user device 12 via one or more additional peripheral devices 13 (not shown), e.g., a mouse, keyboard, touch inputs to the display screen 14, etc., when developing or designing state transition tables for the FSM-modeled system, including functions of resident software and/or hardware thereof. The present solutions are intended to facilitate the downstream verification of system behavior subsequent to the proper and thorough design of an FSM and corresponding state transition table(s). Among the many possible attendant benefits of the present solutions, the user 11 is better able to identify, within the larger design, precisely where the design is not well structured and lacks adequate hierarchy.

As part of the present strategy, the host computer 12 of FIG. 1 or its constituent processing nodes 12A, 12B, . . . , 12N of FIG. 1A may be equipped with non-transitory, tangible computer-readable storage medium or memory (M) 54 having non-transitory instructions stored thereon, and one or more processors (P) 56, e.g., logic circuits, combinational logic circuit(s), Application Specific Integrated Circuit(s) (ASIC), electronic circuit(s), central processing unit(s), semiconductor IC devices, etc., as well as input/output (I/O) circuit(s), appropriate signal conditioning and buffer circuitry, and other components such as a high-speed clock to provide the described functionality. The associated memory 54 may include application-suitable amounts and types of non-transitory memory inclusive of read only, programmable read only, random access, a hard drive, etc., whether resident, remote or a combination of both.

As a precursor to performing the method 100M of FIG. 3, the user device 12 illustrated in FIG. 1 receives system traits 15 and user inputs 16 from the user 11. This action could entail receiving various states, state transitions, and events of the modeled system, along with a possible “super-events” (event combinations), hierarchy definitions, and other system traits 15 for the FSM-modeled system. In response to the received system traits 15, the user device 12 automatically generates and outputs a first data set 17 embodying a blank/unpopulated initial state transition table (Ti) 19. This initial state transition table 19 is indexed by as complete of a population of possible states and events of the modeled system as possible, and with the system traits 15 entered by the user 11. Additionally, the user device 12 in some embodiments automatically populates the initial state transition table 19 with a second data set 18 to generate a third data set 19S, with the third data set 19S including a populated state transition table (“Tₚ”) 20.

That is, the user device 12 automatically generates (“auto-generates”) the populated state transition table 20 in response to the system traits 15 and other user inputs 16. After performing one or more iterations, the user device 12 ultimately outputs a final state transition table (T_{F}) 21, which may be given as a set of transitions, nodes, diagrams, etc. The final state transition table 21 may serve as data 110 associated with the design of the FSM-modeled system, with the data 110 used by a pattern recognition platform 25 in accordance with the disclosure. The user inputs 16 may also include similar information for existing designs 18 for other existing systems that have been previously reviewed according to FSM processes. The existing designs 18, for example, may include annotations, sequences, best practices, interest, issues, and other characterizations of patterns or pattern inducing elements, features, transitions, etc. therein. The data 110 thus is a starting point for further investigation by the user 11 when performing the method 100M of FIG. 3, when recognizing patterns that the FSM-modeled system exhibits.

Referring briefly to FIG. 2, the automated system 10 of FIG. 1 may involve interaction of the user device 12 and the pattern recognition platform 25. In general, the present approach involves receiving the data 110 associated with a system design, including the various states, state transitions, events, and outputs, which as noted above may include details for existing designs 18. The existing designs 18, the final state table 21 and/or other information described in FIG. 1 may be included with or fully embody the data 110. As contemplated herein, the pattern recognition platform 25 could process and search/analyze the data 110, e.g., via a suitable search algorithm, for the existence of predetermined behavior and/or other desired properties, such as to search for or otherwise identify system patterns appearing therein. The system patterns, for example, may be determined based on comparison to the existing designs 18 included as part of the data 110. The designer may be correspondingly enabled to annotate problematic or good design patterns so that the system learns the patterns associated therewith. The system can learn to flag bad patterns and also flag good patterns. Overtime it may learn from these annotations to better support a designer during his or her work.

The pattern recognition platform 25 would thereafter demarcate, identify, or otherwise “flag” the system patterns within the FSM-modeled system, such by indicating each system pattern to be one of “good”, “bad”, or “of interest” to the design team. A control action may then be performed in response to the recognized system patterns as set forth below. For instance, nominal states S₁, S₂, S₃, and S₄ may be specified in the data 110, potentially with data that describes static properties, dynamic properties, structural properties, states, state transitions, events, and outputs of the FSM-modeled system. As part of the present method 100M of FIG. 3, the pattern recognition platform 25 could thereafter perform one or more control actions associated with the flagging the behavior, for instance by outputting a notification 160 to the user device 12 and/or an external device 22 as part of this action.

The pattern recognition platform 25 of FIGS. 1 and 2 may transmit one or more notifications 160 as specific recommendations for the system patterns. For example, recommendations for locating and identifying the system patterns relative to the nominal states S₁, S₂, S₃, and S₄ could be part of the notifications 160. The user device 12 as part of such an exchange could receive the notification 160 and possibly provide recommendations to the user 11 in response to the notification 160. In some implementations, the pattern recognition platform 25 could be used to identify potential design flaws and provide recommendations/suggestions for correcting state tables or stateflow diagrams, and possibly conserve computing resources (e.g., processors, memory, and/or the like) that might otherwise be wasted. Thus, use of the pattern recognition platform 25 facilitates design of an FSM-modeled system, with improved speed and efficiency of the design process and quality of designs being just some of the attendant benefits beyond processing information in a manner the design team would be unable to undertake individually.

Referring now to FIG. 3, a logic flow diagram is shown that illustrates an embodiment of the present method 100M. The logic flow diagram is constructed from constituent logic segments or blocks, with each block implemented manually and/or automatically as needed, e.g., as one or more algorithms or code segments. Those skilled in the art will appreciate that the flow diagram of FIG. 3 also lends itself to the implementation of constituent hardware/software modules each configured to perform the associated tasks. Thus, the terms “block” and “module” are used hereinbelow synonymously.

Block B101 (System Design Module) feeds into method 100M to enable the user device 12 of FIG. 1 to receive data associated with the design of the FSM-modeled system (“system design”). The system design module/Block B101 provides as complete a record as possible of the states, state transitions, events, and user-facing indications (“outputs”) of the FSM-modeled system. The system design may include data describing static properties, dynamic properties, structural properties, states, state transitions, events, and outputs of the FSM-modeled system. Block B101 is configured for constructing a viable system design for the FSM-modeled system. As appreciated in the art, this effort in turn involves the generation and error-checking of one or more state transition tables and/or transition diagrams, e.g., using the automated approach described in U.S. patent application Ser. No. 18/318,006, filed on May 16, 2023, which is hereby incorporated by reference in its entirety, or using another sufficiently developed state transition table, e.g., the final state transition table 21 of FIG. 1. Such data is received at block B102 as inputs to the method 100M.

Block B102 (Hypothesis Generation Module) feeds into method 100M to enable the user device 12 of FIG. 1 to receive data associated with Block B103 (Existing Designs) of previously modeled systems (“existing designs”). B102 may, for example, consider structural and static properties of existing patterns to form a generalizable hypothesis for future identification of patterns in the FSM-modeled system. A designer may be correspondingly enabled to annotate all structures for which she or he has a hunch that they can be problematic. These may be structures that passed the formal incorrectness verification, yet the designer still feels that it is problematic. The same can be done for “good” properties. The existing design module/Block B103 provides as complete a record as possible of the states, state transitions, events, and user-facing indications (“outputs”) for the existing designs. The existing designs may include data describing static properties (B104), dynamic properties (B105), structural properties (B106) for the states, state transitions, events, outputs, etc., of the existing designs. B102 may include a hypothesis generation process (B107) for generalizing the existing designs, and marking or training based thereon to generate a design analysis model. The design analysis model or similar construct may be used for making potential patterns in the system design for the FSM-modeled system based on the occurrence of corresponding patterns in the existing designs.

Block B110 (Design Scanner Module) identifies one or more system patterns within the FSM-modeled system based on scanning the system design for the FSM-modeled system according to the design analysis model. This may include generalizing a given set of annotated/marked locations of system patterns in existing designs derived in B107 to scan for locations of similar or related patterns in the system design of the FSM-modeled system (“system patterns”). Block B111 (Likelihood Estimation Module) generates a pattern score for each of the system patterns (“pattern scores”). The pattern scores may be determined using any general function, such as but not necessarily limited to at least one of a weighted average or a sigmoid function. Block B112 (Threshold Module) provides one or more threshold scores for comparison with one or more of the pattern scores. The threshold scores may be predetermined from the user device or calculated with the user device. Block B113 (Notifications Module) generates a notification to indicate one or more actions for the FSM-modeled system based on comparing the pattern scores to the threshold scores associated therewith, which may occur on an individual basis for each of the scanned system patterns. The notification may be operable for identifying one or more of the system patterns as at least one of good, bad, and of interest to a design team and/or include an identification and location within the FSM-modeled system for one or more of the system patterns.

In this manner, the design scanner uses pattern matching of graphs to score (estimate) the likelihood of each substructure, similar efforts are done from the static properties' perspective. There is an aggregation and unification of the scores (static and structural) to a single measurement of likelihood. Parts of the system design are being analyzed using the hypothesis generator, eventually, there is a single likelihood estimation for each subgraph for how likely it is to be a pattern, e.g., it may be an estimate of how likely the subgraph could be an instance (or resemble) a bad design pattern. This may be done by using graph matching techniques.

One aspect of the present disclosure relates to recognizing patterns within an FSM-modeled system. The types of patterns recognized may vary depending on a number of factors, such as the patterns derived from annotated or existing designs. i.e., previously developed FSM-modeled systems. The patterns, for example, may be used to identify patterns sharing common characteristics indicated by the states and the type of interaction between states. The present solutions are intended to support designers in improving the quality of their designs by automatically identifying both bad and good patterns in their system design. The disclosure describes an automatic identification of fault patterns in a system designed using artificial intelligence methods. The artificial intelligence methods involve training models using state diagrams annotated/marked with the locations of system patterns. The patterns may share common characteristics indicated by the states and the type of interaction between states. The present solutions are intended to support designers in improving the quality of their designs by using a design-scanner platform to automatically identify patterns in a system design, where the identification is based on artificial intelligence models trained with annotated designs. The models are used to identify locations in a design that have a high likelihood of being indicative of a pattern for the design team to consider.

The data may include static properties and structural properties of each state. A static property describes an attribute of a state or an aspect of its behavior. Examples of state properties include, but are not limited to, physical properties, displayable objects with their properties (visual cues), audio cues, textual content, and any other arbitrary properties that are system dependent. A structural property describes the relationship (i.e., topology and patterns of connections) between a state and its actions to other states and their actions, where the relationship is not system dependent. Edges and vertices form structural properties within a design. According to graph theory, a vertex, a point where multiple lines meet (where a point is a particular position in a one-dimensional, two-dimensional, or three-dimensional space). An edge is the mathematical term for a line that connects two vertices. Many edges may be formed from a single vertex. Without a vertex, an edge cannot be formed. A starting vertex and an ending vertex is required for an edge. Structural properties include graph patterns that are used as hypotheses for identifying patterns with the FSM-modeled system. A graph pattern comprising a subset of states and transitions (edges). For example, two or more states that are connected by a bidirectional edge.

The pattern recognition platform 25 may analyze the design data and extract static properties and structural properties from the design data for processing and scoring. The design analysis may analyze the design data in parts and identify the location of the system patterns in the data. For structural properties, graph matching techniques are used to extract the structural properties. Good patterns: hierarchy, global events, logical arrangement, semantic arrangement, criticality arrangements. Bad patterns: no hierarchy, too many local events, illogical arrangement with respect to system operations (e.g., multiple overlapping modes), critical components (e.g., ability to respond to a Traffic Device or not) do not receive proper designation in the state machine diagram. One skilled in the art would readily recognize examples of graph matching techniques, such as a recursive backtracking procedure for solving the subgraph isomorphism problem, a heuristics based analysis, the Glasgow Subgraph solver, etc.

The pattern recognition platform 25 may process the design to determine a design score associated with the design data. Using the extracted static properties and structural properties, the pattern recognition platform 25 may assign a design score to the design data, which is equivalent to assigning a design score to the design. To assign a design score, the pattern recognition platform 25 may use pattern matching of graphs for structural properties and may use a similar method of pattern matching for static properties. The design score may be an aggregate score based on the overall probability of the design data containing a pattern. The aggregate score combines the probability of structural properties containing a pattern and the probability of static properties containing a pattern. The probability of structural properties is based on the structure of subgraph of a stateflow diagram and may be represented by the following equation: P(G=Design Fault|structure (G)).

The probability of static properties is based on the static properties of states and transitions and may be represented by the following equation: P(G=Design pattern|static (v₁, v₂, vₖ)).

The aggregate score may be represented by the following equation: P(G=Design pattern|structure(G), static (v₁, v₂, vₖ)).

The pattern recognition platform 25 may use a linear scoring method for determining the design score. Examples of linear scoring methods include, but are not limited to, weighted average and weighted sum of the impact factors. The pattern recognition platform 25 may use nonlinear scoring methods for determining the design score. Examples of nonlinear scoring methods include, but are not limited to, sigmoid function (or sigmoid scoring functions). The pattern recognition platform 25 may determine whether the design score satisfies a threshold score. The threshold score represents a likelihood estimation that a design contains a pattern. The threshold score may be predetermined. The threshold score may be updated by a user. The threshold score may be determined automatically by the pattern recognition platform 25 based on artificial intelligence methods and historical data.

The pattern recognition platform 25 may perform one or more actions associated with the design based on whether the design score satisfies the threshold score. Once the design score has satisfied the threshold score, the pattern recognition platform 25 or another module may perform the action of transmitting a notification. The pattern recognition platform 25 may perform the action of providing the data associated with the satisfied threshold to the pattern recognition platform 25 for updating the pattern recognition platform 25. The pattern recognition platform 25 may train a model with historical data. The pattern recognition platform 25 may use one or more artificial intelligence techniques, such as machine learning (i.e., machine learning algorithm), deep learning, and/or the like to train and/or generate a pattern recognition platform 25. The historical data contain static properties and/or structural properties associated with patterns.

After existing system patterns (good, bad, faults, of interest, etc.) are identified, the designs containing the patterns are provided to the pattern recognition platform 25 for training. The pattern recognition platform 25 uses the static properties and structural properties of the designs to determine patterns and to create a model based on the patterns identifying the patterns. The model is used for identifying patterns in future designs. The pattern recognition platform 25 may include a smart data manipulation and integration model based on business rules, a machine learning model, a neural network model, a deep learning model, and/or the like that analyzes a massive amount of data (i.e., an amount of data that cannot be processed objectively by a human actor), recognizes patterns among the data, and makes a prediction without requiring a person to program specific instructions. The pattern recognition platform 25 may separate the historical data into a training set, a validation set, a test set, and/or the like. The training set may be utilized to train the pattern recognition platform 25. The validation set may be utilized to validate results of the pattern recognition platform 25. The test set may be utilized to test the operation of the pattern recognition platform 25.

The pattern recognition platform 25 or another module may train the pattern recognition platform 25 using, for example, an unsupervised training procedure and the historical data. For example, the pattern recognition platform 25 may perform dimensionality reduction to reduce the historical data to a minimum feature set, thereby reducing resources (e.g., processing resources, memory resources, and/or the like) to train the neural network, and may apply a classification technique to the minimum feature set. The pattern recognition platform 25 may use a logistic regression classification technique to determine a categorical outcome (e.g., static properties and structural properties associated with patterns). Additionally, or alternatively, the pattern recognition platform 25 may use a naïve Bayesian classifier technique. In this case, the pattern recognition platform 25 may perform binary recursive partitioning to split the historical data into partitions and/or branches, and use the partitions and/or branches to determine outcomes (e.g., static properties and structural properties associated with patterns). Based on using recursive partitioning, the pattern recognition platform 25 may reduce utilization of computing resources relative to manual, linear sorting and analysis of data points, thereby enabling use of thousands, millions, or billions of data points to train the machine learning model, which may result in more accurate models than using fewer data points.

The pattern recognition platform 25 may use a support vector machine (SVM) classifier technique to generate a non-linear boundary between data points in the training set. In this case, the non-linear boundary is used to classify test data into a particular class. The pattern recognition platform 25 may train the pattern recognition platform 25 using a supervised training procedure that includes receiving input to the pattern recognition platform 25 from a subject matter expert, which may reduce an amount of time, an amount of processing resources, and/or the like to train the pattern recognition platform 25 relative to an unsupervised training procedure. The pattern recognition platform 25 may train the pattern recognition platform 25 using a graph convolutional network (GCN), graph attention network (GAT), graph isomorphism network (GIN), and/or the like. GCN solves node and graph classification tasks. GAT solves node and graph classification tasks by focusing on essential nodes. GIN is used for solving classification problems that involve nodes and graphs by leveraging the structural information of graphs.

The pattern recognition platform 25 may train the pattern recognition platform 25 using a convolutional neural network (CNN) and a recurrent neural network (RNN). A CNN is a deep, feed-forward artificial neural network composed of neurons that have learnable weights and biases. A RNN is feed-forward neural network that focuses on modeling in the temporal domain. The pattern recognition platform 25 may use one or more other model training techniques, such as a neural network technique, a latent semantic indexing technique, and/or the like. For example, the pattern recognition platform 25 may perform an artificial neural network processing technique (e.g., using a two-layer feedforward neural network architecture, a three-layer feedforward neural network architecture, and/or the like) to perform pattern recognition with regard to patterns of the historical data. In this case, using the artificial neural network processing technique may improve an accuracy of the pattern recognition platform 25 generated by the pattern recognition platform 25 by making the pattern recognition platform 25 more robust to noisy, imprecise, or incomplete data, and by enabling the pattern recognition platform 25 to detect patterns and/or trends undetectable to human analysts or systems using less complex techniques.

Optionally, rather than training the model, the pattern recognition platform 25 may obtain the pattern recognition platform 25 from another system or device that trained the pattern recognition platform 25 to generate the pattern recognition platform 25. In this case, the pattern recognition platform 25 may provide the other system or device with the historical data for use in training the model, and may provide the other system or device with updated historical data to retrain the pattern recognition platform 25 in order to update the pattern recognition platform 25. In this way, using the design-scanner platform conserves computing resources (e.g., processors, memory, and/or the like) that would otherwise be wasted in design cycle of a system design because the design-scanner platform alerts users to potential patterns.

For purposes of the present description, unless specifically disclaimed, use of the singular includes the plural and vice versa, the terms “and” and “or” shall be both conjunctive and disjunctive, and the words “including,” “containing,” “comprising,” “having,” and the like shall mean “including without limitation.” Moreover, words of approximation such as “about,” “almost,” “substantially,” “generally,” “approximately,” etc., may be used herein in the sense of “at, near, or nearly at,” or “within 0-5% of,” or “within acceptable manufacturing tolerances,” or logical combinations thereof. As used herein, a component that is “configured to” perform a specified function is capable of performing the specified function without alteration, rather than merely having potential to perform the specified function after further modification. In other words, the described hardware, when expressly configured to perform the specified function, is specifically selected, created, implemented, utilized, programmed, and/or designed for the purpose of performing the specified function.

The detailed description and the drawings or figures are supportive and descriptive of the present teachings, but the scope of the present teachings is defined solely by the claims. While some of the best modes and other embodiments for carrying out the present teachings have been described in detail, various alternative designs and embodiments exist for practicing the present teachings defined in the appended claims. Moreover, this disclosure expressly includes combinations and sub-combinations of the elements and features presented above and below.

What is claimed is:

1. A pattern recognition platform, comprising:
a system design module configured for receiving data associated with a design of a finite state machine (FSM)-modeled system from a user device, wherein the data describes static properties, dynamic properties, structural properties, states, state transitions, events, and outputs of the FSM-modeled system;
a hypothesis generation module configured for determining a design analysis model from one or more existing designs, the design analysis model operable for training pattern searching of the FSM-modeled system according to the static properties, dynamic properties, structural properties, states, state transitions, events, and outputs; and
a design scanner module configured for identifying one or more system patterns within the FSM-modeled system based on searching the FSM-modeled system according to the design analysis model.

2. The pattern recognition platform according to claim 1, further comprising:
a likelihood estimation module configured for generating a pattern score for each of the system patterns.

3. The pattern recognition platform according to claim 2, further comprising:
a threshold module configured for providing one or more threshold scores for comparison with one or more of the pattern scores.

4. The pattern recognition platform according to claim 3, further comprising:
a notifications module configured for generating a notification to indicate one or more actions for the FSM-modeled system based on comparing the pattern scores to threshold scores.

5. The pattern recognition platform according to claim 4, wherein:
the notification is operable for identifying one or more of the system patterns as at least one of good, bad, and of interest to a design team.

6. The pattern recognition platform according to claim 5, wherein:
the notification includes an identification and location within the FSM-modeled system for one or more of the system patterns.

7. The pattern recognition platform according to claim 6, wherein:
the static properties include attributes and behaviors for one or more of the states.

8. The pattern recognition platform according to claim 7, wherein:
the structural properties include one or more graph patterns for a subset of one or more of the states and the state transitions.

9. The pattern recognition platform according to claim 8, wherein:
the dynamic properties include one more equations or mathematical representation for a subset of one more of the states and the state transitions.

10. The pattern recognition platform according to claim 9, wherein:
the hypothesis generation module is configured for determining the design analysis model using at least one of a machine learning algorithm and a neural network.

11. The pattern recognition platform according to claim 10, wherein:
the hypothesis generation module is configured for determining the design analysis model using one or more annotated or existing designs.

12. The pattern recognition platform according to claim 11, wherein:
the annotated or existing designs includes information associated with determining the identification and the location of the one or more system patterns within the FSM-modeled system.

13. The pattern recognition platform according to claim 12, wherein:
one or more of the pattern scores are determined using at least one of a weighted average or a sigmoid function.

14. The pattern recognition platform according to claim 13, wherein:
one or more of the threshold scores are predetermined from the user device or calculated with the user device.

15. A method for pattern recognition, comprising:
receiving data associated with a design of a finite state machine (FSM)-modeled system from a user device;
determining a design analysis model from one more annotated or existing designs; and
identifying one or more system patterns within the FSM-modeled system based on searching the FSM-modeled system according to the design analysis model.

16. The method according to claim 15, further comprising:
training pattern searching of the FSM-modeled system according to static properties, dynamic properties, structural properties, states, state transitions, events, and outputs identified for the FSM-modeled system.

17. The method according to claim 15, further comprising:
generating a pattern score for each of the system patterns;
providing one or more threshold scores for comparison with one or more of the pattern scores; and
generating a notification to indicate one or more actions for the FSM-modeled system based on comparing the pattern scores to the threshold scores.

18. The method according to claim 15, further comprising:
identifying one or more of the system patterns as at least one of good, bad, and of interest to a design team.

19. A pattern recognition platform, comprising:
a system design module configured for receiving data associated with a design of a finite state machine (FSM)-modeled system;
a hypothesis generation module configured for determining a design analysis model from one or more existing designs;
a design scanner module configured for identifying one or more system patterns within the FSM-modeled system based on searching the FSM-modeled system according to the design analysis model;
a likelihood estimation module configured for generating a pattern score for each of the system patterns;
a threshold module configured for providing one or more threshold scores for comparison with one or more of the pattern scores; and
a notifications module configured for generating a notification to indicate one or more actions for the FSM-modeled system based on comparing the pattern scores to the threshold scores.

20. The pattern recognition platform according to claim 19, wherein:
the notifications module is configured for identifying one or more of the system patterns as at least one of good, bad, and of interest to a design team.
